(19) United States
(12) Patent Application Publication
(10) Pub. No.: US 2025/0143019 A1
(43) Pub. Date: May 1, 2025

(54) LIGHT-EMITTING DEVICE AND LIGHT-EMITTING APPARATUS

(71) Applicant: TIANJIN SANAN OPTOELECTRONICS CO., LTD., Tianjin (CN)

(72) Inventors: Weihuan LI, Tianjin (CN); Fuyang NING, Tianjin (CN); Liwei WANG, Tianjin (CN); Kunhuang CAI, Tianjin (CN); Xiaofeng LIU, Xiamen (CN); Jin-Dong WEI, Tianjin (CN); Han-Xin LIU, Tianjin (CN)

(21) Appl. No.: 18/771,063

(22) Filed: Jul. 12, 2024

(30) Foreign Application Priority Data
Oct. 31, 2023 (CN) 202311433284.9

(51) Int. Cl. H01L 33/14; H01L 33/06; H01L 33/62

(52) U.S. Cl. CPC H10H 20/816; H10H 20/812; H10H 20/857

(57) ABSTRACT

A light-emitting device includes a semiconductor epitaxial unit having a first surface and a second surface that are opposite to each other, and including a first semiconductor layer, an active layer, and a second semiconductor layer that are disposed sequentially in such order in a direction from the first surface to the second surface. The active layer includes a quantum well structure that has n periodic units, each of which includes a well layer and a barrier layer that are sequentially disposed. The second semiconductor layer includes a cladding layer and a current spreading layer. A ratio of a thickness of the current spreading layer to a current density of the light-emitting device ranges from 0.6 to 4. A light-emitting apparatus is also provided in the disclosure.

### CROSS-REFERENCE TO RELATED APPLICATION

This application claims priority to Chinese Invention Patent Application No. 202311433284.9, filed on Oct. 31, 2023, the entire disclosure of which is incorporated by reference herein.

### FIELD

The disclosure relates to semiconductor field, and more particularly to a light-emitting device and a light-emitting apparatus.

### BACKGROUND

Light-emitting diodes (LEDs) offer advantages including high luminous intensity, high efficiency, small size, long lifespan, etc., are considered to be one of the light sources having the most potential, and have been widely used in various fields.

However, the LEDs still face many challenges, including efficiency droop. That is to say, under low operating current, the LEDs have high external quantum efficiency (EQE). However, as operating current rises, the external quantum efficiency drops, and hence the efficiency droop.

Conventionally, to achieve the high luminous intensity, high power LEDs often operate under high current density. Due to the efficiency droop, the external quantum efficiency of the high power LEDs is limited, thereby limiting luminous efficiency of the high power LEDs. At the same time, improving saturation current and a hot-cold factor of the LEDs are important tasks. The hot-cold factor of the LEDs is related to the luminous intensity and operating temperature of the LEDs. The better the hot-cold factor of the LEDs, the better the LEDs perform under high temperature. Optimizing design of an epitaxial structure of a LED is important in improving the luminous intensity, the saturation current, and the hot-cold factor of the LED.

### SUMMARY

Therefore, an object of the disclosure is to provide a light-emitting device and a light-emitting apparatus that can alleviate at least one of the drawbacks of the prior art.

According to a first aspect of the disclosure, the light-emitting device includes a semiconductor epitaxial unit having a first surface and a second surface that are opposite to each other, and including a first semiconductor layer, an active layer, and a second semiconductor layer that are disposed sequentially in such order in a direction from the first surface to the second surface. The active layer includes a quantum well structure that has n periodic units, each of which includes a well layer and a barrier layer that are sequentially disposed. The second semiconductor layer includes a cladding layer and a current spreading layer.

A ratio of a thickness of the current spreading layer to a current density of the light-emitting device ranges from 0.6 to 4.

According to a second aspect of the disclosure, a light-emitting apparatus includes a driving unit and a light-emitting device electrically connected to the driving unit. The light-emitting device includes a semiconductor epitaxial unit that has a first surface and a second surface opposite to each other, and that includes a first semiconductor layer, an active layer, and a second semiconductor layer disposed sequentially in such order in a direction from the first surface to the second surface. The active layer includes a quantum well structure that has n periodic units, each of which includes a well layer and a barrier layer that are sequentially disposed. The second semiconductor layer includes a cladding layer and a current spreading layer.

A ratio of a thickness of the current spreading layer to a current density of the light-emitting device ranges from 0.6 to 4.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a semiconductor epitaxial structure according to an embodiment of the disclosure.

FIG. 2 is a schematic view illustrating a light-emitting device according to the embodiment of the disclosure.

FIGS. 3 and 4 are schematic views illustrating a method for manufacturing a light-emitting device according to an embodiment of the disclosure.

FIG. 5 is a schematic view illustrating a light-emitting device according to an embodiment of the disclosure.

FIGS. 6 to 8 are schematic views illustrating a method for manufacturing the light-emitting device of FIG. 5.

FIG. 9 is a schematic view illustrating a light-emitting apparatus according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

The present disclosure provide various embodiments of a light-emitting device. Based on an operating current density of the light-emitting device, a thickness of a current spreading layer and a structure of an active layer of the light-emitting device are adjusted accordingly, so as to improve a saturation current, a hot-cold factor, and light-emitting efficiency of the light-emitting device.

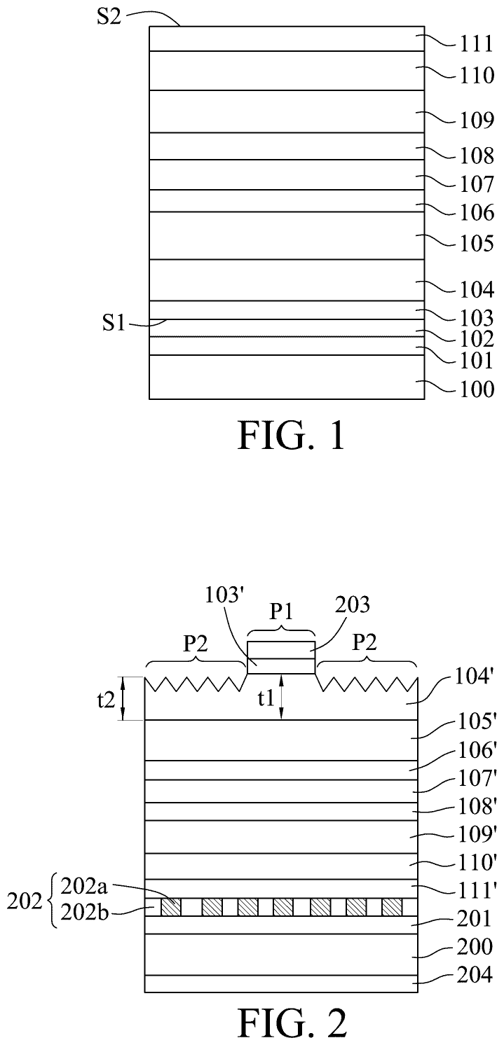

Referring to FIG. 1, an embodiment of a semiconductor epitaxial structure according to this disclosure is to be used to form embodiments of the light-emitting device of this disclosure and includes a growth substrate 100 and a semiconductor epitaxial laminate formed on the growth substrate 100. The semiconductor epitaxial laminate includes a first current spreading layer 104, a first cladding layer 105, a first spacing layer 106, an active layer 107, a second spacing layer 108, a second cladding layer 109, a second current spreading layer 110, and a second ohmic contact layer 111 sequentially disposed in such order in a direction away from the growth substrate 100.

Specifically, referring to FIG. 1, the growth substrate 100 may be made of, but is not limited to, GaAs, GaP, InP, etc. In this embodiment, the growth substrate 100 is made of GaAs. In some embodiments, the semiconductor epitaxial structure further includes a buffer layer 101 and an etch stop layer 102, and the semiconductor epitaxial laminate further includes a first ohmic contact layer 103. The first ohmic contact layer 103 is disposed on the first current spreading layer 104 opposite to the first cladding layer 105, and the buffer layer 101 and the etch stop layer 102 are disposed between the growth substrate 100 and the first current spreading layer 104. Due to lattice quality of the buffer layer 101 being better than that of the growth substrate 100, forming the buffer layer 101 on the growth substrate 100 may alleviate adverse effects of lattice defects of the growth substrate 100 on the semiconductor epitaxial laminate. The etch stop layer 102 serves to terminate etching in an etching procedure. In certain embodiments, the etch stop layer 102 is an n-type etch stop layer made of n-GaInP. To facilitate removal of the growth substrate 100, a thickness of the etch stop layer 102 is greater than 0 nm and no greater than 500 nm. In some embodiments, the thickness of the etch stop layer 102 is greater than 0 nm and no greater than 200 nm. In some embodiments, the first ohmic contact layer 103 is made of GaAs, and has a thickness ranging from 10 nm to 100 nm, and a doping concentration ranging from 1E18/cm³ to 10E18/cm³. In certain embodiments, the doping concentration of the first ohmic contact layer 103 is 2E18/cm³ so as to achieve better ohmic contact.

The semiconductor epitaxial laminate may be formed on the growth substrate 100 by using methods such as physical vapor deposition (PVD), chemical vapor deposition (CVD), epitaxy growth technology, atomic layer deposition (ALD), etc. The semiconductor epitaxial laminate may contain a semiconductor material that generates light, such as ultra-violet light, blue light, green light, yellow light, red light, and infrared light. Specifically, the semiconductor material of the semiconductor epitaxial laminate may be a material that generates light having a wavelength which ranges from 200 nm to 950 nm, such as a nitride material. In certain embodiments, the semiconductor epitaxial laminate may be a GaN-based laminate that may be doped with aluminum, indium, etc. and may generate light that has a wavelength ranging from 200 nm to 550 nm. In other embodiments, the semiconductor epitaxial laminate is an AlGaInP-based laminate or an AlGaAs-based laminate that generates light having a wavelength which ranges from 550 nm to 950 nm.

The semiconductor epitaxial laminate has a first surface (S1) and a second surface (S2) that are opposite to each other, and includes a first semiconductor layer, the active layer 107, and a second semiconductor layer that are disposed sequentially in such order in a direction from the first surface (S1) to the second surface (S2) (i.e., in the direction away from the growth substrate 100).

The first semiconductor layer and the second semiconductor layer may be respectively an n-type doped semiconductor layer and a p-type doped semiconductor layer for providing electrons and holes, respectively. The n-type doped semiconductor layer may be doped with an n-type dopant such as Si, Ge, or Sn, and the p-type doped semiconductor layer may be doped with a p-type dopant such as Mg, Zn, Ca, Sr, C, or Ba. When the first semiconductor layer is the n-type doped semiconductor layer, the second semiconductor layer is the p-type doped semiconductor layer; when the first semiconductor layer is the p-type doped semiconductor layer, the second semiconductor layer is the n-type doped semiconductor layer. The first semiconductor layer, the active layer 107, and the second semiconductor layer may be made of materials such as aluminum gallium indium nitride, gallium nitride, aluminum gallium nitride, aluminum indium phosphorus, aluminum gallium indium phosphorus, gallium arsenide, aluminum gallium arsenic, etc. In this embodiment, the first semiconductor layer is the n-type doped semiconductor layer, and the second type semiconductor layer is the p-type doped semiconductor layer.

The first semiconductor layer includes the first cladding layer 105 made of AlGaInP, AlInP, or AlGaAs that provides one of the electrons and the holes for the active layer 107, and the second semiconductor layer includes the second cladding layer 109 made of AlGaInP, AlInP, or AlGaAs that provides another one of the electrons and the holes for the active layer 107. In some embodiments, when the active layer 107 includes AlGaInP, each of the first cladding layer 105 and the second cladding layer 109 may include AlInP to provide the electrons and the holes. To enhance uniformity of current spreading, the first semiconductor layer further includes the first current spreading layer 104, and the second semiconductor layer further includes the second current spreading layer 110.

To prevent dopants in the first cladding layer 105 and the second cladding layer 109 from diffusing into the active layer 107 and affecting lattice quality of the active layer 107, in this embodiment, the first spacing layer 106 is disposed between the first cladding layer 105 and the active layer 107, and the second spacing layer 108 is disposed between the second cladding layer 109 and the active layer 107.

The first current spreading layer 104 serves to spread current, and its ability of current spreading depends on its thickness. The first current spreading layer 104 may include a material that is represented by Al_{y1}Ga_{1-y1}InP, and has a thickness that ranges from 2500 nm to 4000 nm, and an n-type doping concentration that ranges from 2E17/cm³ to 4E18/cm³. In some embodiments, the first current spreading layer 104 has the n-type doping concentration that ranges from 4E17/cm³ to 2E18/cm³. A common n-type dopant include Si, but other equivalent elements may be used.

The first spacing layer 106 is disposed between the first cladding layer 105 and the active layer 107, includes a material that is represented by Alₐ₁Ga₁₋ₐ₁InP, where a1 may range from 0.2 to 1, and has a thickness that is smaller than 120 nm. In this embodiment, the first spacing layer 106 is n-type doped, and has a doping concentration smaller than 2E17/cm³.

The first cladding layer 105 serves to provide the electrons for the active layer 107, may include AlInP, and has a thickness ranging from 300 nm to 1500 nm. A common n-type dopant of the first cladding layer 105 includes Si, but other equivalent elements may be used.

The active layer 107 is a light emitting area for the electrons and the holes to recombine. Depending on a wavelength of light emitted by the active layer 107, materials for the active layer 107 may vary. The active layer 107 may be a single quantum well or multiple quantum wells with a periodic structure. In this embodiment, the active layer 107 includes a quantum well structure that has n periodic units, each of which includes a well layer and a barrier layer that are sequentially disposed. A bandgap of the barrier layer is greater than that of the well layer. By adjusting a composition of a semiconductor material of the active layer 107, when the electrons and the holes recombine, the light having a pre-determined wavelength is emitted. The material of the active layer 107, such as AlGaInP or AlGaAs, exhibits electroluminescence property. In some embodiments, the active layer 107 is made of AlGaInP with a single quantum well or multiple quantum wells. In this embodiment, the semiconductor epitaxial laminate is made of an AlGaInP-based material and emits an infrared light that has a wavelength ranging from 550 nm to 750 nm.

Each of the well layers includes a material that is represented by AlₓGa₁₋ₓInP, and each of the barrier layers includes a material that is represented by Al_{y2}Ga_{1-y2}InP, where 0≤x≤y2≤1. Each of the wells layer has a thickness ranging from 2 nm to 25 nm. In some embodiments, the thickness of each of the well layers ranges from 8 nm to 20 nm. Each of the barrier layers has a thickness ranging from 2 nm to 25 nm. In some embodiments, the thickness of each of the barrier layers ranges from 10 nm to 20 nm. Each of the barrier layers has an aluminum content (y2) that ranges from 0.3 to 0.85.

The second spacing layer 108 is disposed on the active layer 107, includes a material that is represented by Al_{b}Ga_{1-b}InP, has a thickness that is smaller than 300 nm, and has a doping concentration that is smaller than 1E17/cm³. An aluminum content (b) of the second spacing layer 108 ranges from 0.3 to 1. In some embodiments, the aluminum content (b) of the second spacing layer 108 is greater than 0.5 and smaller than 1.

The second semiconductor layer includes the second cladding layer 109, the second current spreading layer 110, and the second ohmic contact layer 111. The second cladding layer 109 serves to provide the holes for the active layer 107, may include AlInP, and has a thickness ranging from 300 nm to 1500 nm. A common p-type dopant of the second cladding layer 109 includes Mg, but other equivalent elements may be used.

The second current spreading layer 110 serves to spread current, and its ability of current spreading depends on its thickness. In this embodiment, the second current spreading layer 110 may have a composition that is represented by Al_{z}Ga_{1-z}InP, and z ranges from 0 to 1. A thickness of the second current spreading layer 110 may be adjusted according to a current density of the light-emitting device, so as to improve a current spreading ability of the light-emitting device under different levels of current density. At the same time, lattice quality of the second current spreading layer 110 is related to its thickness. By virtue of adjusting the thickness of the second current spreading layer 110, the lattice quality of the second current spreading layer 110 may be improved, which may reduce dislocations and light absorption points in the second current spreading layer 110, and improve internal quantum efficiency of the light-emitting device, thereby improving an operating current, the saturation current, the hot-cold factor, and the light-emitting efficiency of the light-emitting device. In some embodiments, a ratio of the thickness of the second current spreading layer 110 to the current density of the light-emitting device ranges from 0.6 to 4. In some embodiments, the ratio of the thickness of the second current spreading layer 110 to the current density of the light-emitting device ranges from 0.8 to 3.2.

Under a medium-high current density, such as the current density being greater than 1 A/mm², the thickness of the second current spreading layer 110 ranges from 1.0 μm to 2.5 μm. Under a low current density, such as the current density being smaller than or equal to 1 A/mm², the thickness of the second current spreading layer 110 ranges from 0.2 μm to 1.0 μm.

As a number of the periodic units of the active layer 107 increases, the internal quantum efficiency of the light-emitting device increases, a probability of minority carriers recombining in the active layer 107 increases, and the light-emitting device may withstand a higher current. Therefore, the number of the periodic units of the active layer 107 under different levels of current and current density has significant impact on the light-emitting efficiency of the light-emitting device. In this embodiment, the number of the periodic units of the active layer 107 is adjusted according to different levels of current density and a size of the light-emitting device, so as to achieve an ideal light-emitting efficiency of the light-emitting device under the different levels of current density.

In some embodiments where a current applied to the light-emitting device is relatively low, when the current density of the light-emitting device is greater than 1 A/mm² and when the size of the light-emitting device is smaller than 140 μm*140 μm, the number of the periodic units ranges from 6 to 20. In some embodiments, the number of the periodic units ranges from 10 to 20.

In other embodiments where a current applied to the light-emitting device is relatively high, when the current density of the light-emitting device is greater than 1 A/mm² and when the size of the light-emitting device is smaller than 1000 μm*1000 μm, the number of the periodic units ranges from 20 to 45. In some embodiments, the number of the periodic units ranges from 25 to 45.

In certain embodiments, when the current density of the light-emitting device is smaller than or equal to 1 A/mm², the number of the periodic units ranges from 12 to 45. In some embodiments, the number of the periodic units ranges from 15 to 45.

In this embodiment, the second current spreading layer 110 is made of GaP, and has a p-type doping concentration that ranges from 6E17/cm³ to 2E18/cm³. A common p-type dopant include Mg and C, but other equivalent elements may be used.

The second ohmic contact layer 111 forms an ohmic contact with a second electrode 204 (to be described later), is made of GaP, and has a doping concentration greater than 1E19/cm³. In some embodiment, the doping concentration of the second ohmic contact layer 111 is greater than 5E19/cm³ so as to achieve better ohmic contact. A thickness of the second ohmic contact layer 111 ranges from 40 nm to 150 nm. In this embodiment, the thickness of the second ohmic contact layer 111 is 60 nm.

FIG. 2 illustrates an embodiment of a light-emitting device according to this disclosure which is produced from the semiconductor epitaxial structure of FIG. 1. The light-emitting device is mainly used in fields such as outdoor display, plant lighting, stage lights, etc. In this embodiment, the thickness of the second current spreading layer 110 is adjusted according to the current density of the light-emitting device, which may improve the current spreading ability of the light-emitting device under different levels of current density, thereby improving the saturation current, the hot-cold factor, and light-emitting efficiency of the light-emitting device.

The light-emitting device includes a supporting substrate 200 and a semiconductor epitaxial unit. The light-emitting device may further include a bonding layer 201 for bonding the semiconductor epitaxial unit to the supporting substrate 200. The semiconductor epitaxial unit is formed by patterning the semiconductor epitaxial laminate shown in FIG. 1, and thus has a layer structure similar to that of the semiconductor epitaxial laminate shown in FIG. 1. The semiconductor epitaxial unit includes a second ohmic contact layer 111′, a second current spreading layer 110′, a second cladding layer 109′, a second spacing layer 108′, an active layer 107′, a first spacing layer 106′, a first cladding layer 105′, a first current spreading layer 104′, and a first ohmic contact layer 103′ sequentially disposed in such order on the supporting substrate 200 and in a direction away from the supporting substrate 200. The second ohmic contact layer 111′, the second current spreading layer 110′, the second cladding layer 109′, the second spacing layer 108′, the active layer 107′, the first spacing layer 106′, the first cladding layer 105′, the first current spreading layer 104′, and the first ohmic contact layer 103′ are respectively formed from the second ohmic contact layer 111, the second current spreading layer 110, the second cladding layer 109, the second spacing layer 108, the active layer 107, the first spacing layer 106, the first cladding layer 105, the first current spreading layer 104, and the first ohmic contact layer 103 of FIG. 1, and thus have the same compositions and structures. It is noted that the first current spreading layer 104′ and the first ohmic contact layer 103′ are formed by patterning the first current spreading layer 104 and the first ohmic contact layer 103 (to be described below).

The supporting substrate 200 is a conductive substrate and may be made of silicon, silicon carbide or metal. Examples of the metal include copper, tungsten, molybdenum, etc. In some embodiments, the supporting substrate 200 has a thickness no smaller than 50 μm so as to have sufficient mechanical strength to support the semiconductor epitaxial unit. In addition, during formation of the light-emitting device, to facilitate further mechanical processing of the supporting substrate 200 after bonding the semiconductor epitaxial laminate shown in FIG. 1 to the supporting substrate 200, the supporting substrate 200 may have a thickness that is no greater than 300 μm. In this embodiment, the supporting substrate 200 is a silicon substrate.

The light-emitting device further includes a first electrode 203 and a second electrode 204. The first electrode 203 is disposed on the first ohmic contact layer 103. The first electrode 203 and the first ohmic contact layer 103 form an ohmic contact to allow an electric current to pass therethrough. During formation of the light-emitting device, the first ohmic contact layer 103 of the semiconductor epitaxial laminate is patterned to maintain a portion of the first ohmic contact layer 103 located right below the first electrode 203 so as to obtain the first ohmic contact layer 103′. The first current spreading layer 104′ includes two portions in a horizontal direction perpendicular to the direction from the first surface (S1) to the second surface (S2): a first portion (P1) that is located right below and covered by the first ohmic contact layer 103′ and the first electrode 203, and a second portion (P2) that is not located right below and that is exposed from the first electrode 203. The second portion (P2) has a light-exiting surface. The light-exiting surface may surround the first electrode 203 and be a patterned surface or a roughened surface obtained via, e.g., etching. The light-exiting surface may have a regular or an arbitrarily irregular micro/nanostructure. The light-exiting surface that is patterned or roughened facilitates an exit of light, so as to increase the luminous efficiency of the light-emitting device. In some embodiments, the light-exiting surface is a roughened surface that has a roughened structure with a height difference (between the highest and lowest point of the roughened structure) of less than 1 μm, e.g., from 10 nm to 300 nm.

Of the first current spreading layer 104′, the first portion (P1) has a contact surface that is in contact with the first ohmic contact layer 103′. The contact surface is not roughened because the contact surface is protected by the first electrode 203. The roughened surface of the second portion (P2) of the first current spreading layer 104′ is relatively lower than the contact surface of the first portion (P1) on a horizontal level.

Specifically, as shown in FIG. 2, in this embodiment, the first portion (P1) has a first thickness (t1). The second portion (P2) has a second thickness (t2). In certain embodiments, the first thickness (t1) ranges from 1.5 μm to 2.5 μm, and the second thickness (t2) ranges from 0.5 μm to 1.5 μm. The first thickness (t1) of the first portion (P1) is greater than the second thickness (t2) of the second portion (P2). In some embodiments, the first thickness (t1) is greater than the second thickness (t2) by at least 0.3 μm.

The light-emitting device may further include a mirror layer 202 that is disposed between the semiconductor epitaxial unit and the supporting substrate 200. The mirror layer 202 includes an ohmic contact metal sublayer 202a and the dielectric sublayer 202b. On one hand, the ohmic contact metal sublayer 202a and the dielectric sublayer 202b cooperate with the second ohmic contact layer 110 to form an ohmic contact. On the other hand, the ohmic contact metal sublayer 202a and the dielectric sublayer 202b reflect the light emitted by the active layer 107 toward the light-exiting surface or a side wall of the semiconductor epitaxial unit so as to facilitate the exit of light.

The second electrode 204 may be disposed on the supporting substrate 200 at a side where the semiconductor epitaxial unit is disposed or at a side opposite to the semiconductor epitaxial unit. In this embodiment, the second electrode 204 is disposed on the supporting substrate 200 opposite to the semiconductor epitaxial unit.

Each of the first electrode 203 and the second electrode 204 may include a transparent conductive material or a metallic material. When each of the first electrode 203 and the second electrode 204 is made of a transparent conductive material, each of the first electrode 203 and the second electrode 204 is formed as a transparent conductive layer. The transparent conductive material may be indium tin oxide (ITO) or indium zinc oxide (IZO). The metallic material may be GeAuNi, AuGe, AuZn, Au, Al, Pt, and Ti, and combinations thereof.

In this embodiment, based on the operating current density of the light-emitting device, the thickness of the current spreading layer and a structure of the active layer of the light-emitting device are adjusted accordingly, so as to improve the current spreading ability, internal quantum efficiency, the saturation current, the hot-cold factor, and light-emitting efficiency of the light-emitting device.

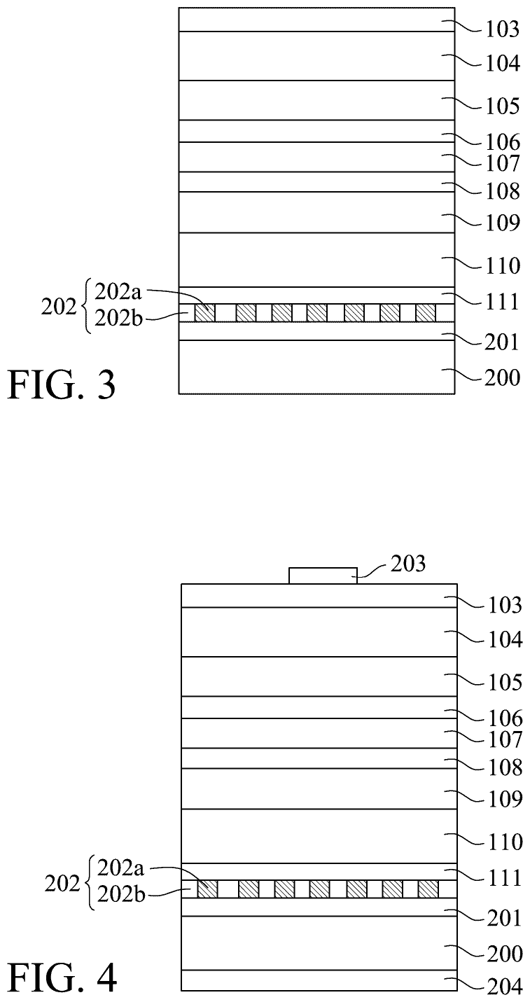

FIGS. 3 to 4 are schematic diagrams illustrating a method for manufacturing the light-emitting device shown in FIG. 2. Detailed descriptions are given below in connection with the schematic diagrams.

First, the semiconductor epitaxial structure as shown in FIG. 1 is provided. Specifically, the growth substrate 100 is provided, and the buffer layer 101, the etch stop layer 102 and the semiconductor epitaxial laminate are grown on the growth substrate 100 using an epitaxy process, such as metal-organic chemical vapor deposition (MOCVD). The semiconductor epitaxial laminate includes the first ohmic contact layer 103, the first current spreading layer 104, the first cladding layer 105, the first spacing layer 106, the active layer 107, the second spacing layer 108, the second cladding layer 109, the second current spreading layer 110, and the second ohmic contact layer 111 sequentially disposed in such order on the growth substrate 100.

Next, the semiconductor epitaxial laminate is transferred onto the supporting substrate 200, and the growth substrate 100, the buffer layer 101 and the etch stop layer 102 are removed, so as to obtain a structure as shown in FIG. 3. Specifically, the mirror layer 202 is formed on the second ohmic contact layer 111, and includes the ohmic contact metal sublayer 202a and the dielectric sublayer 202b. On one hand, the ohmic contact metal sublayer 202a and the dielectric sublayer 202b cooperate to form an ohmic contact with the second ohmic contact layer 111. On the other hand, the ohmic contact metal sublayer 202a and the dielectric sublayer 202b reflect light emitted by the active layer 107. Next, the supporting substrate 200 is provided, and the bonding layer 201 is provided on the supporting substrate 200, followed by bonding the supporting substrate 200 and the mirror layer 202 on the semiconductor epitaxial laminate together, and removing the growth substrate 100. When the growth substrate 100 is made of GaAs, wet etching may be conducted for removing of the growth substrate 100, the buffer layer 101, and the etch stop layer 102 until the first ohmic contact layer 103 is revealed.

Next, referring to FIG. 4, the first electrode 203 is formed on the first ohmic contact layer 103, and a good ohmic contact is established between the first electrode 203 and the first ohmic contact layer 103. The second electrode 204 is formed on the supporting substrate 200 at the side opposite to the semiconductor epitaxial laminate, thereby allowing current to flow among the first electrode 203, the second electrode 204, and the semiconductor epitaxial laminate. The supporting substrate 200 has a certain thickness so as to provide sufficient mechanical strength to support the semiconductor epitaxial laminate.

Then, a mask (not shown) is provided to cover the first electrode 203, and a portion of the first ohmic contact layer 103 that is not covered by and surrounds the first electrode 203 is left exposed (i.e., not covered by the mask). Next, etching is performed to remove the portion of the first ohmic contact layer 103 that is left exposed, so as to form the first ohmic contact layer 103′ and to partially expose the first current spreading layer 104. Afterwards, the first current spreading layer 104 is etched to form the patterned or roughened surface so as to form the first current spreading layer 104′ as shown in FIG. 2. It should be noted that the removal of the exposed portion of the first ohmic contact layer 103 and the roughening of the first current spreading layer 104 may be conducted by wet etching in one step or multiple steps. An etchant used for wet etching may be an acidic solution, such as hydrochloric acid, sulfuric acid, hydrofluoric acid, citric acid, or other chemical reagents.

Finally, depending on requirements, processes such as etching or dicing are performed to obtain a plurality of the light-emitting devices.

The light-emitting device is mainly used in fields such as outdoor display, plant lighting, stage lights, etc. Under the medium-high current density, such as greater than 1 A/mm², the thickness of the second current spreading layer 110 ranges from 1.0 μm to 2.5 μm. Under the low current density, such as smaller than or equal to 1 A/mm², the thickness of the second current spreading layer 110 ranges from 0.2 μm to 1.0 μm. In this embodiment, the thickness of the second current spreading layer 110 is adjusted according to the current density of the light-emitting device, which may improve the current spreading ability of the light-emitting device, thereby improving the saturation current, the hot-cold factor, and light-emitting efficiency of the light-emitting device.

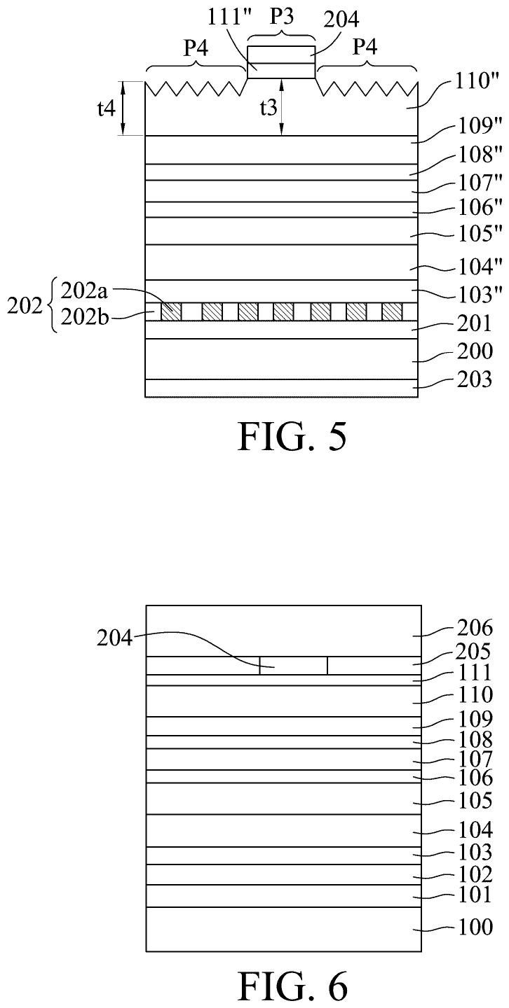

FIG. 5 illustrates another embodiment of the light-emitting device according to the disclosure which is produced from the semiconductor epitaxial structure of FIG. 1. Referring to FIG. 5, the light-emitting device includes a supporting substrate 200 and a semiconductor epitaxial unit. The light-emitting device further includes a bonding layer 201 for bonding the semiconductor epitaxial unit to the supporting substrate 200. The semiconductor epitaxial unit includes a first ohmic contact layer 103″, a first current spreading layer 104″, a first cladding layer 105″, a first spacing layer 106″, an active layer 107″, a second spacing layer 108″, a second cladding layer 109″, a second current spreading layer 110″, and a second ohmic contact layer 111″ sequentially disposed in such order on the supporting substrate 200 and in the direction away from the supporting substrate 200.

The supporting substrate 200 is a conductive substrate and may be made of silicon, silicon carbide or metal. Examples of the metal include copper, tungsten, molybdenum, etc. In some embodiments, the supporting substrate 200 has a thickness no smaller than 50 μm so as to have sufficient mechanical strength to support the semiconductor epitaxial unit.

In addition, during formation of the light-emitting device, to facilitate further mechanical processing of the supporting substrate 200 after bonding the semiconductor epitaxial laminate shown in FIG. 1 to the supporting substrate 200, the supporting substrate 200 may have a thickness that is no greater than 300 μm. In this embodiment, the supporting substrate 200 is a copper substrate.

The light-emitting device further includes a first electrode 203 and a second electrode 204. The second electrode 204 is disposed on the second ohmic contact layer 111. The second electrode 204 and the second ohmic contact layer 111 form an ohmic contact to allow an electric current to pass therethrough. During formation of the light-emitting device, the second ohmic contact layer 111 of the semiconductor epitaxial laminate is patterned to maintain a portion of the second ohmic contact layer 111 located right below the second electrode 204 so as to obtain the second ohmic contact layer 111″. The second current spreading layer 110 includes two portions in a horizontal direction perpendicular to the direction from the first surface (S1) to the second surface (S2): a third portion (P3) that is located right below and covered by the second ohmic contact layer 111″ and the second electrode 204, and a fourth portion (P4) that is not located right below the second electrode 204 and that is exposed from the second electrode 204. The fourth portion (P4) has a light-exiting surface. The light-exiting surface may surround the second electrode 204 and be a patterned surface or a roughened surface obtained via e.g., etching. The light-exiting surface may have a regular or an arbitrarily irregular micro/nanostructure. The light-exiting surface that is patterned or roughened facilitates an exit of light, so as to increase the luminous efficiency of the light-emitting device. In some embodiments, the light-exiting surface is a roughened surface that has a roughened structure with a height difference (between the highest and lowest point of the roughened structure) of less than 1 μm, e.g., from 10 nm to 300 nm.

Of the second current spreading layer 110″, the third portion (P3) has a contact surface that is in contact with the second ohmic contact layer 111″. The contact surface is not roughened because the contact surface is protected by the second electrode 204. The roughened surface of the fourth portion (P4) of the second current spreading layer 110″ is relatively lower than the contact surface of the third portion (P3) on a horizontal level.

Specifically, as shown in FIG. 5, in this embodiment, the third portion (P3) has a third thickness (t3). The fourth portion (P4) has a fourth thickness (t4). In certain embodiments, the third thickness (t3) ranges from 1.5 μm to 2.5 μm, and the fourth thickness (t4) ranges from 0.5 μm to 1.5 μm. The third thickness (t3) of the third portion (P3) is greater than the fourth thickness (t4) of the fourth portion (P4). In some embodiments, the third thickness (t3) is greater than the fourth thickness (t4) by at least 0.3 μm.

The light-emitting device may further include the mirror layer 202 that is disposed between the semiconductor epitaxial unit and the supporting substrate 200. The mirror layer 202 includes the ohmic contact metal sublayer 202a and the dielectric sublayer 202b. On one hand, the ohmic contact metal sublayer 202a and the dielectric sublayer 202b cooperate with the second ohmic contact layer 110 to form an ohmic contact. On the other hand, the ohmic contact metal sublayer 202a and the dielectric sublayer 202b reflect the light emitted by the active layer 107 toward the light-exiting surface or the side wall of the semiconductor epitaxial unit so as to facilitate the exit of light.

The light-emitting device further includes the first electrode 203. In some embodiments, the first electrode 203 is disposed on the supporting substrate 200 at the side where the semiconductor epitaxial unit is disposed or at the side opposite to the semiconductor epitaxial unit.

Each of the first electrode 203 and the second electrode 204 may include a transparent conductive material or a metallic material. When each of the first electrode 203 and the second electrode 204 is made of a transparent conductive material, each of the first electrode 203 and the second electrode 204 is formed as a transparent conductive layer. The transparent conductive material may be indium tin oxide (ITO) or indium zinc oxide (IZO). The metallic material may be GeAuNi, AuGe, AuZn, Au, Al, Pt, and Ti, and combinations thereof.

In this embodiment, based on the operating current density of the light-emitting device, the thickness of the current spreading layer of the light-emitting device is adjusted accordingly, so as to improve the current spreading ability, the saturation current, the hot-cold factor, and light-emitting efficiency of the light-emitting device.

FIGS. 6 to 8 are schematic diagrams illustrating a method for manufacturing the light-emitting device shown in FIG. 5. Detailed descriptions are given below in connection with the schematic diagrams.

First, the semiconductor epitaxial structure as shown in FIG. 1 is provided. Specifically, the growth substrate 100 is provided, and the buffer layer 101, the etch stop layer 102 and the semiconductor epitaxial laminate are grown on the growth substrate 100 using an epitaxy process, such as metal-organic chemical vapor deposition (MOCVD). The semiconductor epitaxial laminate includes the first ohmic contact layer 103, the first current spreading layer 104, the first cladding layer 105, the first spacing layer 106, the active layer 107, the second spacing layer 108, the second cladding layer 109, the second current spreading layer 110, and the second ohmic contact layer 111 sequentially disposed in such order on the growth substrate 100.

In this embodiment, the growth substrate 100 is made of GaAs, and a material of the growth substrate 100 may depend on a material of the buffer layer 101. It should be noted that, the material of the growth substrate 100 is not limited to GaAs, GaP, InP, etc. may also be used. The etch stop layer 102 (i.e., GaInP) is disposed on the buffer layer 101. To facilitate the removal of the growth substrate 100, the thickness of the etch stop layer 102 is greater than 0 nm and no greater than 500 nm. In some embodiments, the thickness of the etch stop layer 102 is greater than 0 nm and no greater than 200 nm.

Then, referring to FIG. 6, the second electrode 204 is formed on the second ohmic contact layer 110. A bonding adhesive 205 is used to bond the semiconductor epitaxial laminate along with the second electrode 204 to a temporary substrate 206. In some embodiments, the bonding adhesive is a benzocyclobutene (BCB) adhesive, and the temporary substrate 206 is a glass substrate.

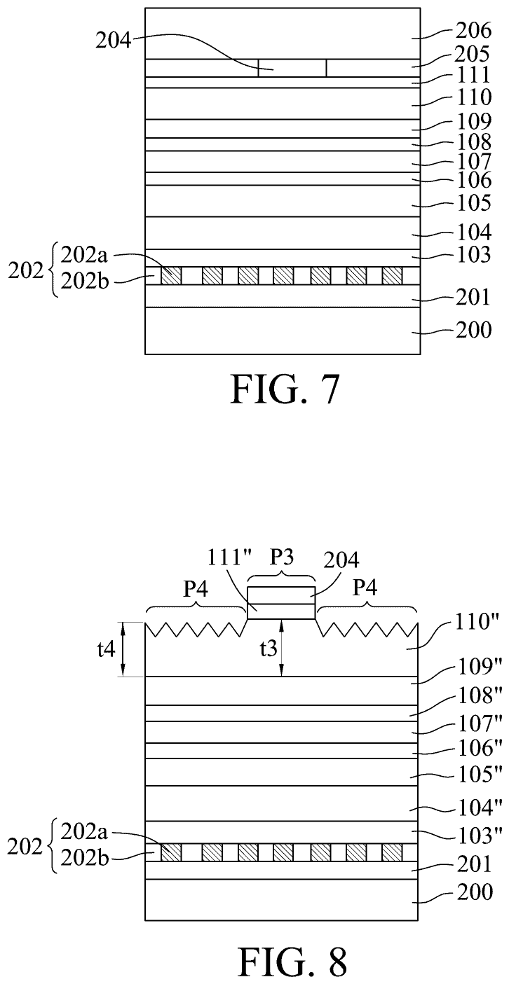

Next, wet etching is conducted to remove the growth substrate 100, the buffer layer 101, and the etch stop layer 102 so that the first ohmic contact layer 103 is exposed. The mirror layer 202 is then formed on the first ohmic contact layer 103, and includes the ohmic contact metal sublayer 202a and the dielectric sublayer 202b. On one hand, the ohmic contact metal sublayer 202a and the dielectric sublayer 202b cooperate to form an ohmic contact with the first ohmic contact layer 103. On the other hand, the ohmic contact metal sublayer 202a and the dielectric sublayer 202b reflect light emitted by the active layer 107. Next, the supporting substrate 200 is provided, and the bonding layer 201 is provided on the supporting substrate 200 to bond the supporting substrate 200 and the mirror layer 202 together, so as to obtain a structure as shown in FIG. 7.

Then, wet etching is conducted to remove the temporary substrate 206 and the bonding adhesive 205. The mask (not shown) is provided to cover the second electrode 204, and the portion of the second ohmic contact layer 111 that is not covered by and surrounds the second electrode 204 is left exposed (i.e., not covered by the mask). Next, etching is performed to remove the portion of the second ohmic contact layer 111 that is left exposed, so as to form the second ohmic contact layer 111″ and to partially expose the second current spreading layer 110. Afterwards, the second current spreading layer 110 is etched to form the second current spreading layer 110″ as shown in FIG. 8. It should be noted that the removal of the exposed portion of the second ohmic contact layer 111 and the roughening of the second current spreading layer 110 may be conducted by wet etching in one step or multiple steps. An etchant used for wet etching may be an acidic solution, such as hydrochloric acid, sulfuric acid, hydrofluoric acid, citric acid, or other chemical reagents.

Finally, the first electrode 203 is formed on the supporting substrate 200 at the side opposite to the semiconductor epitaxial unit. Depending on requirements, processes such as etching or dicing are performed to obtain a plurality of light-emitting devices, as shown in FIG. 5.

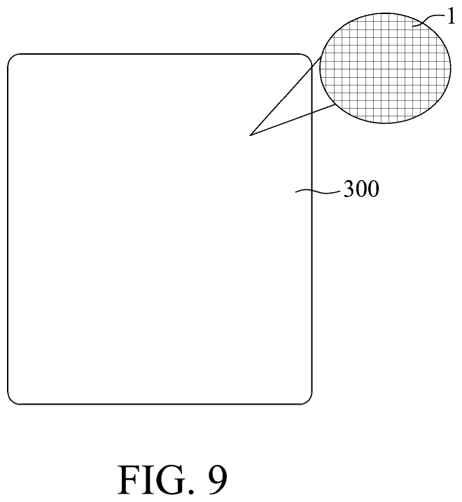

Referring to FIG. 9, an embodiment of a light-emitting apparatus 300 according to the disclosure is provided and includes a driving unit and a light-emitting device 1 which is electrically connected to the driving unit. The light-emitting device 1 is as described in any one of the previous embodiments. In this embodiment, the light-emitting apparatus 300 includes a plurality of the light-emitting devices 1 arranged in an array. In FIG. 9, a portion of the light-emitting devices 1 is enlarged and schematically shown.

For the light-emitting device and the light-emitting apparatus according to the disclosure, based on the operating current density and the size of the light-emitting device, the thickness of the second current spreading layer 110′ of the light-emitting device is adjusted accordingly, so as to improve the current spreading ability, the saturation current, the hot-cold factor, and light-emitting efficiency of the light-emitting device. Therefore, the light-emitting device of the light-emitting apparatus may achieve an ideal light-emitting efficiency under different levels of current density.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial unit having a first surface and a second surface that are opposite to each other, and including a first semiconductor layer, an active layer, and a second semiconductor layer that are disposed sequentially in such order in a direction from said first surface to said second surface, said active layer including a quantum well structure that has n periodic units, each of which includes a well layer and a barrier layer that are sequentially disposed, said second semiconductor layer including a cladding layer and a current spreading layer,
wherein a ratio of a thickness of said current spreading layer to a current density of said light-emitting device ranges from 0.6 to 4.

2. The light-emitting device as claimed in claim 1, wherein the ratio of said thickness of said current spreading layer to the current density of said light-emitting device ranges from 0.8 to 3.2.

3. The light-emitting device as claimed in claim 1, wherein when the current density of said light-emitting device is greater than 1 A/mm², said thickness of said current spreading layer ranges from 1.0 μm to 2.5 μm.

4. The light-emitting device as claimed in claim 1, wherein when the current density of said light-emitting device is smaller than or equal to 1 A/mm², said thickness of said current spreading layer ranges from 0.2 μm to 1.0 μm.

5. The light-emitting device as claimed in claim 3, wherein when the current density of said light-emitting device is greater than 1 A/mm² and when a size of said light-emitting device is smaller than 140 μm*140 μm, a number of said periodic units ranges from 6 to 20.

6. The light-emitting device as claimed in claim 3, wherein when the current density of said light-emitting device is greater than 1 A/mm² and when a size of said light-emitting device is smaller than 1000 μm*1000 μm, a number of said periodic units ranges from 20 to 45.

7. The light-emitting device as claimed in claim 4, wherein when the current density of said light-emitting device is smaller than or equal to 1 A/mm², a number of said periodic units ranges from 12 to 45.

8. The light-emitting device as claimed in claim 1, wherein said current spreading layer is p-type doped and has a doping concentration that ranges from 6E17/cm³ to 2E18/cm³.

9. The light-emitting device as claimed in claim 1, wherein said current spreading layer is made of GaP.

10. The light-emitting device as claimed in claim 1, wherein said active layer emits light that has a wavelength ranging from 550 nm to 950 nm.

11. A light-emitting apparatus, comprising a driving unit and a light-emitting device electrically connected to said driving unit, said light-emitting device including a semiconductor epitaxial unit that has a first surface and a second surface opposite to each other, and that includes a first semiconductor layer, an active layer, and a second semiconductor layer disposed sequentially in such order in a direction from said first surface to said second surface, said active layer including a quantum well structure that has n periodic units, each of which includes a well layer and a barrier layer that are sequentially disposed, said second semiconductor layer including a cladding layer and a current spreading layer,
wherein a ratio of a thickness of said current spreading layer to a current density of said light-emitting device ranges from 0.6 to 4.

12. The light-emitting apparatus as claimed in claim 11, wherein the ratio of said thickness of said current spreading layer to the current density of said light-emitting device ranges from 0.8 to 3.2.

13. The light-emitting apparatus as claimed in claim 11, wherein when the current density of said light-emitting device is greater than 1 A/mm², said thickness of said current spreading layer ranges from 1.0 μm to 2.5 μm.

14. The light-emitting apparatus as claimed in claim 11, wherein when the current density of said light-emitting device is smaller than or equal to 1 A/mm², said thickness of said current spreading layer ranges from 0.2 μm to 1.0 μm.

15. The light-emitting apparatus as claimed in claim 11, wherein when the current density of said light-emitting device is greater than 1 A/mm² and when a size of said light-emitting device is smaller than 140 μm*140 μm, a number of said periodic units ranges from 6 to 20.

16. The light-emitting apparatus as claimed in claim 11, wherein when the current density of said light-emitting device is greater than 1 A/mm² and when a size of said light-emitting device is smaller than 1000 μm*1000 μm, a number of said periodic units ranges from 20 to 45.

17. The light-emitting apparatus as claimed in claim 11, wherein when the current density of said light-emitting device is smaller than or equal to 1 A/mm², a number of said periodic units ranges from 12 to 45.

18. The light-emitting apparatus as claimed in claim 11, wherein said current spreading layer has a composition that is represented by Al_{z}Ga_{1-z}InP, where z ranges from 0 to 1.

19. The light-emitting apparatus as claimed in claim 11, wherein said current spreading layer is made of GaP.

20. The light-emitting apparatus as claimed in claim 11, wherein said active layer emits light that has a wavelength ranging from 550 nm to 950 nm.
